(19) United States
(12) Patent Application Publication
(10) Pub. No.: US 2013/0040820 A1
(43) Pub. Date: Feb. 14, 2013

(54) FAULT CURRENT LIMITER INCORPORATING A SUPERCONDUCTING ARTICLE AND A HEAT SINK

(71) Applicants: Venkat Selvamanickam, Houston, TX (US); Xun Zhang, Edison, NJ (US); Yi-Yuan Xie, Waterford, NY (US); Drew W. Hazelton, Selkirk, NY (US)

(72) Inventors: Venkat Selvamanickam, Houston, TX (US); Xun Zhang, Edison, NJ (US); Yi-Yuan Xie, Waterford, NY (US); Drew W. Hazelton, Selkirk, NY (US)

(73) Assignee: SuperPower, Inc., Schenectady, NY (US)

(21) Appl. No.: 13/209,233

(22) Filed: Aug. 12, 2011

(51) Int. Cl. H01L 39/02; H02H 9/00; H02H 9/02

(52) U.S. Cl. 505/237; 361/93.1

(57) ABSTRACT

A fault current limiting (FCL) article comprising a superconducting tape segment comprising a substrate, a buffer layer overlying the substrate, a high temperature superconducting (HTS) layer overlying the buffer layer, and a heat sink overlying the HTS layer, where the heat sink is comprised of a non-metal material, a thermal conductivity of not less than about 0.1 W/m-K at 20° C., an electrical resistivity of not less than about 1E-5 Ω-m at 20° C., and a shunting circuit electrically connected to the superconducting tape segment.

### CROSS-REFERENCE TO RELATED APPLICATION(S)

Not applicable.

### BACKGROUND

1. Field of the Disclosure

The present disclosure is directed to fault current limiters, and is particularly directed to fault current limiters utilizing superconducting articles.

2. Description of the Related Art

Current limiting devices are critical in electric power transmission and distribution systems. For various reasons, such as lightning strikes, grounded wires or animal interference, short circuit conditions can develop in various sections of a power grid causing a sharp surge in current. If this surge of current, which is often referred to as fault current, exceeds the protective capabilities of the switchgear equipment deployed throughout the grid system, it could cause catastrophic damage to the grid equipment and customer loads that are connected to the system.

Superconductors, especially high-temperature superconducting (HTS) materials, are well suited for use in a current limiting device because the effect of a “variable impedance” under certain operating conditions. Early generation materials include low-temperature superconductors (low-T_{c} or LTS) exhibiting superconducting properties at temperatures requiring use of liquid helium (4.2 K), have been known since 1911. However, it was not until somewhat recently that oxide-based high-temperature (high-T_{c}) superconductors have been discovered. Around 1986, a first high-temperature superconductor (HTS), having superconducting properties at a temperature above that of liquid nitrogen (77 K) was discovered, namely YBa₂Cu₃O₇₋ₓ (YBCO), followed by development of additional materials over the past 20 years including Bi₂Sr₂Ca₂Cu₃O_{10+y} (BSCCO), and others. The development of high-T_{c} superconductors has created the potential of economically feasible development of superconductor components and other devices incorporating such materials, due partly to the cost of operating such superconductors with liquid nitrogen rather than the comparatively more expensive cryogenic infrastructure based on liquid helium.

Of the myriad of potential applications, the industry has sought to develop use of such materials in the power industry, including applications for power generation, transmission, distribution, and storage. In this regard, it is estimated that the inherent resistance of copper-based commercial power components is responsible for billions of dollars per year in losses of electricity, and accordingly, the power industry stands to gain based upon utilization of high-temperature superconductors in power components such as transmission and distribution power cables, generators, transformers, and fault current interrupters/limiters. In addition, other benefits of high-temperature superconductors in the power industry include a factor of 3-10 increase of power-handling capacity, significant reduction in the size (i.e., footprint) and weight of electric power equipment, reduced environmental impact, greater safety, and increased capacity over conventional technology. While such potential benefits of high-temperature superconductors remain quite compelling, numerous technical challenges continue to exist in the production and commercialization of high-temperature superconductors on a large scale.

Among the challenges associated with the commercialization of high-temperature superconductors, many exist around the fabrication of a superconducting tape segment that can be utilized for formation of various power components. A first generation of superconducting tape segment includes use of the above-mentioned BSCCO high-temperature superconductor. This material is generally provided in the form of discrete filaments, which are embedded in a matrix of noble metal, typically silver. Although such conductors may be made in extended lengths needed for implementation into the power industry (such as on the order of a kilometer), due to materials and manufacturing costs, such tapes do not represent a widespread commercially feasible product.

Accordingly, a great deal of interest has been generated in the so-called second-generation HTS tapes that have superior commercial viability. These tapes typically rely on a layered structure, generally including a flexible substrate that provides mechanical support, at least one buffer layer overlying the substrate, the buffer layer optionally containing multiple films, an HTS layer overlying the buffer film, and an optional capping layer overlying the superconductor layer, and/or an optional electrical stabilizer layer overlying the capping layer or around the entire structure. However, to date, numerous engineering and manufacturing challenges remain prior to full commercialization of such second generation-tapes and devices incorporating such tapes.

In addition to the obstacles posed by the formation of multilayered superconducting articles, utilization of such superconducting articles in certain applications can pose unique obstacles. Particularly, in light of the ever increasing power consumption, utilization of superconducting articles in components such as fault current limiters (FCL) is desirable. However, unlike the use of superconducting articles in long-length conductors, utilization of multilayered superconducting articles in fault current limiter (FCL) devices have unique requirements. Such articles should have the capacity to handle the increasing power demands, and also be capable of handling severe changes in the system, with enhanced response time, performance and durability.

### SUMMARY

According to one aspect, a fault current limiting (FCL) article includes a superconducting tape segment having a substrate having a thickness of less than about 200 microns, a buffer layer overlying the substrate, a high temperature superconducting (HTS) layer overlying the buffer layer and a bonding layer overlying the HTS layer, the bonding layer having a thermal conductivity of not less than about 0.1 W/m-K at 20° C., and an electrical resistivity of not less than about 1E-6 Ω-cm as measured at 20° C. The FCL further includes a heat sink overlying the bonding layer, the heat sink comprising a non-metal material, a thermal conductivity of not less than about 0.1 W/m-K at 20° C., and an electrical resistivity of not less than about 1E-5 Ω-m at 20° C. and a shunting circuit electrically connected to the superconducting tape segment.

In another aspect, a fault current limiting (FCL) article includes a superconducting tape segment having a substrate, a buffer layer overlying the substrate, a high temperature superconducting (HTS) layer overlying the buffer layer, and a heat sink overlying the HTS layer, the heat sink comprising a non-metal material, a thermal conductivity of not less than about 0.1 W/m-K at 20° C., and an electrical resistivity of not less than about 1E-5 Ω-m at 20° C. The FCL further includes a shunting circuit electrically connected to the superconducting tape segment.

### BRIEF DESCRIPTION OF THE DRAWINGS

The present disclosure may be better understood, and its numerous features and advantages made apparent to those skilled in the art by referencing the accompanying drawings.

FIG. 1 illustrates a perspective view showing the generalized structure of a superconducting article according to an embodiment.

FIG. 2 illustrates a cross sectional view of a portion of a superconducting article including a heat sink according to one embodiment.

FIG. 3 illustrates a cross sectional view of a portion of a superconducting article including a heat sink according to one embodiment.

FIG. 4 illustrates a perspective view of a portion of a superconducting article including a heat sink according to one embodiment.

FIG. 5 illustrates a diagram of a FCL article having a superconducting tape segment having a meandering path design and parallel connected shunt circuit(s) according to one embodiment.

FIG. 6 illustrates a diagram of a FCL article having multiple superconducting tape segments in a meandering path design and parallel connected shunt circuit(s) according to one embodiment.

FIG. 7 illustrates a diagram of a superconducting tape segment having a meandering path design with local tape rotation near a contact point and parallel shunt circuit(s) according to one embodiment.

The use of the same reference symbols in different drawings indicates similar or identical items.

### DESCRIPTION OF THE PREFERRED EMBODIMENT(S)

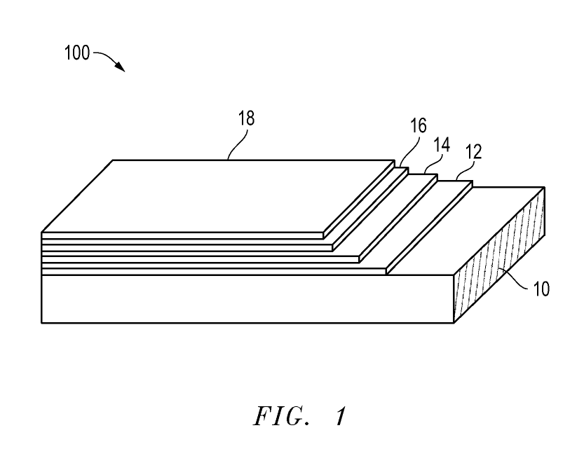

Turning to FIG. 1, the generalized layered structure of a superconducting article 100 according to an embodiment of the present invention is depicted. The superconducting article includes a substrate 10, a buffer layer 12 overlying the substrate 10, a superconducting layer 14, followed by a capping layer 16, typically a noble metal layer, and a stabilizer layer 18, typically a non-noble metal such as copper. The buffer layer 12 may consist of several distinct films. The stabilizer layer 18 may extend around the periphery of the superconducting article 100, thereby encasing it.

The substrate 10 is generally metal-based, and typically, an alloy of at least two metallic elements. Particularly suitable substrate materials include nickel-based metal alloys such as the known Hastelloy® or Inconel® group of alloys. These alloys tend to have desirable creep, chemical and mechanical properties, including coefficient of expansion, tensile strength, yield strength, and elongation. These metals are generally commercially available in the form of spooled tapes, particularly suitable for superconducting tape fabrication, which typically will utilize reel-to-reel tape handling.

The substrate 10 is typically in a tape-like configuration, having a high dimension ratio. As used herein, the term ‘dimension ratio’ is used to denote the ratio of the length of the substrate or tape to the next longest dimension, the width of the substrate or tape. For example, the width of the tape is generally on the order of about 0.4-10 cm, and the length of the tape is typically at least about 10 m, most typically greater than about 50 m. Indeed, superconducting tapes that include substrate 10 may have a length on the order of 100 m or above. Accordingly, the substrate may have a dimension ratio which is fairly high, on the order of not less than 10, not less than about 10², or even not less than about 10³. Certain embodiments are longer, having a dimension ratio of 10⁴ and higher.

In one embodiment, the substrate is treated so as to have desirable surface properties for subsequent deposition of the constituent layers of the superconducting tape. For example, the surface may be polished to a desired flatness and surface roughness. Additionally, the substrate may be treated to be biaxially textured as is understood in the art, such as by the known RABiTS (roll assisted biaxially textured substrate) technique, although embodiments herein typically utilize a non-textured, polycrystalline substrate, such as commercially available nickel-based tapes noted above.

Turning to the buffer layer 12, the buffer layer may be a single layer, or more commonly, be made up of several films. Most typically, the buffer layer includes a biaxially textured film, having a crystalline texture that is generally aligned along crystal axes both in-plane and out-of-plane of the film. Such biaxial texturing may be accomplished by IBAD. As is understood in the art, IBAD is acronym that stands for ion beam assisted deposition, a technique that may be advantageously utilized to form a suitably textured buffer layer for subsequent formation of a superconducting layer having desirable crystallographic orientation for superior superconducting properties. Magnesium oxide is a typical material of choice for the IBAD film, and may be on the order of about 1 to about 500 nanometers, such as about 5 to about 50 nanometers. Generally, the IBAD film has a rock-salt like crystal structure, as defined and described in U.S. Pat. No. 6,190,752, incorporated herein by reference.

The buffer layer may include additional films, such as a barrier film provided to directly contact and be placed in between an IBAD film and the substrate. In this regard, the barrier film may advantageously be formed of an oxide, such as yttria or alumina, and functions to isolate the substrate from the IBAD film. A barrier film may also be formed of non-oxides such as silicon nitride. Suitable techniques for deposition of a barrier film include chemical vapor deposition and physical vapor deposition including sputtering. Typical thicknesses of the barrier film may be within a range of about 1 to about 200 nanometers. Still further, the buffer layer may also include an epitaxially grown film(s), formed over the IBAD film. In this context, the epitaxially grown film is effective to increase the thickness of the IBAD film, and may desirably be made principally of the same material utilized for the IBAD layer such as MgO or other compatible materials.

In embodiments utilizing an MgO-based IBAD film and/or epitaxial film, a lattice mismatch between the MgO material and the material of the superconducting layer exists. Accordingly, the buffer layer may further include another buffer film, this one in particular implemented to reduce a mismatch in lattice constants between the superconducting layer and the underlying IBAD film and/or epitaxial film. This buffer film may be formed of materials such as YSZ (yttria-stabilized zirconia) strontium ruthenate, lanthanum manganate, and generally, perovskite-structured ceramic materials. The buffer film may be deposited by various physical vapor deposition techniques.

While the foregoing has principally focused on implementation of a biaxially textured film in the buffer stack (layer) by a texturing process such as IBAD, alternatively, the substrate surface itself may be biaxially textured. In this case, the buffer layer is generally epitaxially grown on the textured substrate so as to preserve biaxial texturing in the buffer layer. One process for forming a biaxially textured substrate is the process known in the art as RABiTS (roll assisted biaxially textured substrates), generally understood in the art.

The superconducting layer 14 is generally in the form of a high-temperature superconductor (HTS) layer. HTS materials are typically chosen from any of the high-temperature superconducting materials that exhibit superconducting properties above the temperature of liquid nitrogen, 77K. Such materials may include, for example, YBa₂Cu₃O₇₋ₓ, Bi₂Sr₂CaCu₂O_{z}, Bi₂Sr₂Ca₂Cu₃O_{10+y}, Tl₂Ba₂Ca₂Cu₃O_{10+y} and HgBa₂ Ca₂Cu₃O_{8+y}. One class of materials includes (RE)Ba₂Cu₃O₇₋ₓ, wherein RE is a rare earth or combination of rare earth elements. It will be appreciated that non-stoichiometric and stoichiometric variations of such materials can be used, including for example, (RE)_{1.2}Ba_{2.1}Cu_{3.1}O₇₋ₓ. Of the foregoing, YBa₂Cu₃O₇₋ₓ, also generally referred to as YBCO, may be advantageously utilized. YBCO may be used with or without the addition of dopants, such as rare earth materials, for example samarium. The superconducting layer 14 may be formed by any one of various techniques, including thick and thin film forming techniques. Preferably, a thin film physical vapor deposition technique such as pulsed laser deposition (PLD) can be used for a high deposition rates, or a chemical vapor deposition technique can be used for lower cost and larger surface area treatment. Typically, the superconducting layer has a thickness on the order of about 0.1 to about 30 microns, most typically about 0.5 to about 20 microns, such as about 1 to about 5 microns, in order to get desirable amperage ratings associated with the superconducting layer 14.

The superconducting article may also include a capping layer 16 and a stabilizer layer 18, which are generally implemented to provide a low resistance interface and for electrical stabilization to aid in prevention of superconductor burnout in practical use. More particularly, layers 16 and 18 aid in continued flow of electrical charges along the superconductor in cases where cooling fails or the critical current density is exceeded, and the superconducting layer moves from the superconducting state and becomes resistive. Typically, a noble metal or noble metal alloy is utilized for capping layer 16 to prevent unwanted interaction between the stabilizer layer(s) and the superconducting layer 14. Typical noble metals include gold, silver, platinum, and palladium. Silver is typically used due to its cost and general accessibility. The capping layer 16 is typically made to be thick enough to prevent unwanted diffusion of the components from the stabilizer layer 18 into the superconducting layer 14, but is made to be generally thin for cost reasons (raw material and processing costs). Various techniques may be used for deposition of the capping layer 16, including physical vapor deposition, such as DC magnetron sputtering.

The optional stabilizer layer 18 is generally incorporated to overlie the superconducting layer 14, and in particular, overlie and directly contact the capping layer 16 in the particular embodiment shown in FIG. 1. The stabilizer layer 18 functions as an additional protection/shunt layer to enhance stability against harsh environmental conditions and superconductivity quench. The layer is generally dense and thermally and electrically conductive, and functions to bypass electrical current in case of failure of the superconducting layer or if the critical current is exceeded. It may be formed by any one of various thick and thin film forming techniques, such as by laminating a pre-formed copper strip onto the superconducting tape, by using an intermediary bonding material such as a solder. Other techniques have focused on physical vapor deposition, typically evaporation or sputtering, as well as wet chemical processing such as electroless plating, and electroplating. In this regard, the capping layer 16 may function as a seed layer for deposition of copper thereon. Notably, the capping layer 16 and the stabilizer layer 18 may be altered or not used, as described below in accordance with various embodiments.

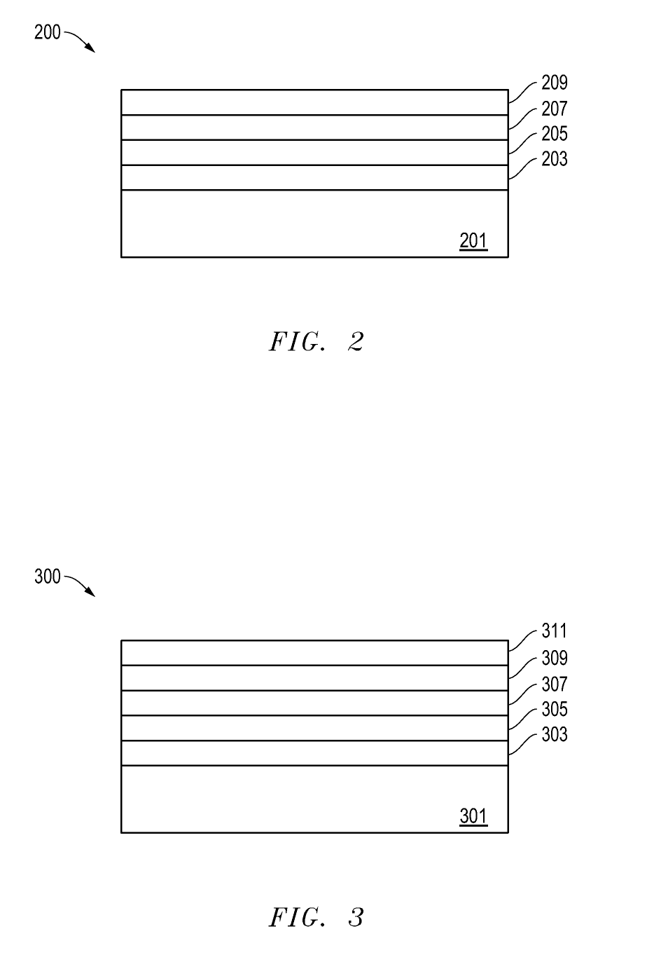

Referring to FIG. 2, a cross-sectional illustration of a superconducting tape segment 200 is illustrated. The superconducting tape segment 200 includes a substrate 201, a buffer layer 203 overlying the substrate 201, and a high-temperature superconducting (HTS) layer 205 overlying the buffer layer 203. Additionally, the superconducting tape segment 200 includes a bonding layer 207 overlying the HTS layer 205 and a heat sink 209 overlying the bonding layer 207.

Such FCL articles typically have a substrate 201 having an average thickness of not greater than about 500 microns. Other embodiments utilize a thinner substrate 201, such that the average thickness is not greater than about 200 microns, such as not greater than about 100 microns, or not greater than about 75 microns, or even not greater than about 50 microns. Generally, the average thickness of the substrate 201 is within a range between about 25 microns and about 125 microns.

Generally, the heat sink 209 can overlie at least a majority of the length of the superconducting tape segment. More particularly, other embodiments utilize a heat sink 209 that is a substantially conformal layer of material overlying the majority of the length of the superconducting segment 200. As such, the heat sink 209 can overlie not less than about 60% of the length of the superconducting tape segment 200, or even not less than about 75% of the total length of the superconducting tape segment 200. In one particular embodiment, the heat sink 209 is a substantially conformal layer overlying essentially the entire length of the superconducting tape segment 200.

Typically, the heat sink 209 is a non-metallic material having a thermal conductivity of not less than about 0.1 W/m-K as measured at 20° C. In other embodiments the heat sink 209 has a greater thermal conductivity, such as not less than about 10 W/m-K, or not less than about 20 W/m-K. Other embodiments utilize a heat sink 209 having a greater thermal conductivity, such as not less than about 100 W/m-K, or not less than about 200 W/m-K, or not less than about 500 W/m-K. According to one particular embodiment, the heat sink 209 includes a non-metallic material having a thermal conductivity of not less than about 1000 W/m-K. Still, the thermal conductivity of the heat sink 209 is generally not greater than about 3000 W/m-K as measured at 20° C.

Notably, the heat sink 209 has a particular electrical resistivity, which is generally not less than about 1E-5 Ω-m as measured at 20° C. In one embodiment, the electrical resistivity of the heat sink 209 can be greater, such as not less than about 1E-3 Ω-m, or not less than about 1E-1 Ω-m. According to another embodiment, the heat sink 209 can have a greater electrical resistivity, such as not less than about 1E2 Ω-m, or even, not less than about 1E8 Ω-m. The electrical resistivity of the heat sink 209 is generally not greater than about 1E12 Ω-m. Still, according to particular embodiments, the electrical resistivity of the heat sink 209 is within a range between about 1E-5 Ω-m and about 1E12 Ω-m, and more particularly within a range between about 1E-5 Ω-m and about 1E4 Ω-m.

The heat sink 209 generally has a low coefficient of linear thermal expansion (CTE), such as not greater than about 300E-6 K⁻¹ as measured at 20° C. Other embodiments utilize a heat sink 209 having a lower CTE, such as not greater than about 100E-6 K⁻¹, or not greater than about 50E-6 K⁻¹, or even not greater than about 10E-6 K⁻¹. Still, some embodiments utilize a heat sink have a lower CTE, such as not greater than about 1E-6 K⁻¹. Typically, the CTE of the heat sink 209 is not less than about 0.25E-6 K⁻¹.

As mentioned above, the heat sink 209 is a non-metallic article, and according to one embodiment, the heat sink 209 is an inorganic material. As used herein, the term non-metal includes materials established as non-metals including ceramics and glasses, as well as those elements on the periodic table classified as metalloids or semi-conducting materials, such as for example, silicon, germanium, arsenic, and others. In one particular embodiment, the heat sink 209 includes carbon, for example, carbon, graphite, diamond, or combinations thereof. As such, the heat sink 209 can be made essentially from carbon, and according to one embodiment, the heat sink 209 includes a sheet of carbon bonded to the HTS layer.

The heat sink 209 can include inorganic compounds, such as compounds including metals and non-metals. According to one embodiment, such inorganic compounds can include borides, carbides, nitrides, oxides, or any combinations thereof. Particularly suitable materials include, silicon carbide, aluminum nitride, beryllium oxide, boron nitride, silicon nitride, and any combinations thereof. According to another embodiment, the heat sink can include silicon, such as for example amorphous polycrystalline silicon.

In one embodiment, the heat sink 209 includes a polycrystalline material consisting of multiple single crystalline grains separated by grain boundaries. According to another embodiment, the heat sink 209 includes a single crystal material. Other embodiments utilize a heat sink 209 including a composite having multiple phases, such as an amorphous phase and a crystalline phase, or multiple distinct crystalline phases.

Generally, the heat sink has an average thickness of not greater than about 5 mm. Other embodiments utilize a thinner heat sink 209, such that the average thickness is not greater than about 4 mm, or not greater than about 3 mm, or not greater than about 2 mm, or even not greater than about 1 mm. Generally, the average thickness is not less than about 1 micron, and according to one particular embodiment, the heat sink has an average thickness within a range between about 10 microns and about 3 mm.

The heat sink 209 can be formed by mechanically attaching the article to the HTS layer 205 or to a bonding layer 207 overlying the HTS layer. Other methods of forming the heat sink 209 can include deposition, such as thick film deposition techniques, for example thermal spraying.

Referring again to FIG. 2, as illustrated, the heat sink 209 is overlying a bonding layer 207 that is overlying the HTS layer 205. According to the illustrated embodiment, the bonding layer 207 is overlying and bonded directly to the HTS layer such that the heat sink 209 is fixably attached to the HTS layer 205 and thus the superconducting tape segment 200. The bonding layer 207 can include an organic or inorganic material, or a combination thereof. Suitable organic materials can include natural or synthetic organic materials. For example, such organic materials can include thermosets, glue, adhesive, epoxy, resin, or combinations thereof. Moreover, such organic materials may include one or more fillers. Such fillers may be organic or inorganic materials. For example, the filler can include a ceramic material, glass material, or another organic, such as for example nylon.

Suitable inorganic materials for forming the bonding layer 207 can include metals, ceramics, glasses, and combinations thereof. In one embodiment, the bonding layer 207 includes a solder, such as those including metals, for example tin, silver, lead and combinations thereof. Alternatively, other solder materials can be used, such as a glass material, including for example, silicates and borates.

Additionally, the bonding layer 207 can have a wide range of electrical resistivity properties depending on its composition, such that the electrical resistivity of the material is not less than about 1E-8 Ω-m as measured at 20° C. More particularly, the electrical resistivity of the bonding layer can be comparable to the electrical resistivity of the heat sink 209, such that it is not less than about 1E-3 Ω-m, or even not less than about 1E2 Ω-m. Generally, the electrical resistivity of the bonding layer 207 is not greater than about 1E12 Ω-m.

Moreover, the CTE of the bonding layer 207 is such that it is generally not greater than about 300 K⁻¹ as measured at 20° C. Other embodiments utilize a bonding layer having a lower CTE, such as not greater than about 50 K⁻¹, or not greater than about 25 K⁻¹, or even not greater than about 15 K⁻¹. Particularly suitable bonding materials have a CTE closely matched to the CTE of the HTS layer 205 and the heat sink 209, such that the CTE is within a range between about 0.25 K⁻¹ and about 50 K⁻¹, and more particularly within a range between about 5 K⁻¹ and about 25 K⁻¹.

As such, the thermal conductivity of the bonding layer 207 is not less than about 0.1 W/m-K as measured at 20° C. In another embodiment, the bonding layer 207 includes a material having a greater thermal conductivity, such as not less than about 10 W/m-K. Other embodiments utilize a bonding layer 207 having a greater thermal conductivity, such as not less than about 100 W/m-K, or not less than about 200 W/m-K, or not less than about 500 W/m-K. According to one particular embodiment, the bonding layer 207 has a thermal conductivity of not less than about 1000 W/m-K. Typically, the thermal conductivity of the bonding layer 207 is generally not greater than about 3000 W/m-K as measured at 20° C.

The bonding layer 207 is generally a thin layer of material, such that the average thickness is not greater than about 3 mm. Other embodiments utilize a thinner layer, such as not greater than about 1 mm, or not greater than about 0.5 mm, or even, not greater than about 0.1 mm. Generally, the average thickness of the bonding layer is not less than about 5 microns.

Referring to FIG. 3, a cross-sectional illustration of a superconducting tape segment 300 is illustrated. The superconducting tape segment 300 includes a substrate 301, a buffer layer 303 overlying the substrate 301, a HTS layer 305 overlying the buffer layer 303 and a capping layer 307 overlying the HTS layer 305. The illustrated embodiment also illustrates a bonding layer 309 overlying the capping layer 307 and a heat sink 311 overlying the bonding layer 309. According to the alternative embodiment illustrated in FIG. 3, the bonding layer 309 and the heat sink 311 are overlying a capping layer, described above.

In such embodiments utilizing a capping layer, typically the capping layer 307 can be thin. That is, the average thickness of the capping layer 307 is generally not greater than about 500 microns. Other embodiments may utilize a thinner capping layer 307, such as not greater than about 100 microns, or not greater than about 10 microns, or even not greater than about 0.1 microns. In one particular embodiment, the superconducting tape segment 300 is essentially free of a capping layer overlying the HTS layer 305.

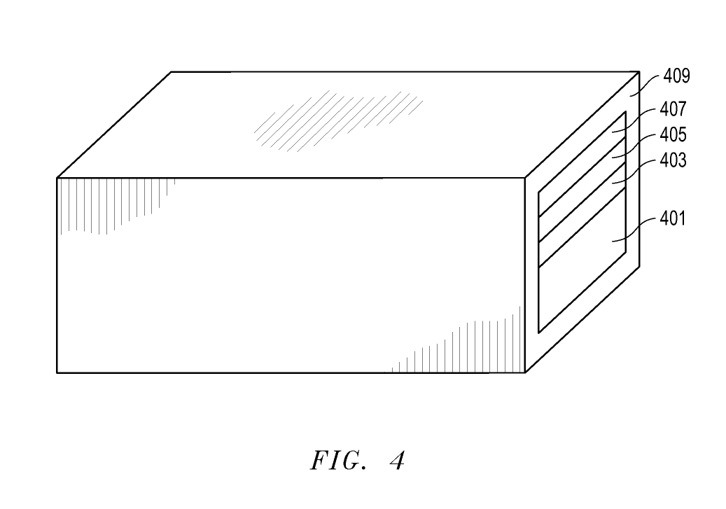

FIG. 4 provides an alternative embodiment of a superconducting tape segment 400 incorporating a heat sink 409. As illustrated, the heat sink 409 is substantially surrounding the layers of the superconducting tape segment 400, which includes the substrate 401, the buffer layer 403, the HTS layer 405, and the optional capping layer 407. This alternative design facilitates contact with more of the layers and the exposed surfaces of the layers within the superconducting tape segment 400. It will be appreciated that such embodiments may utilize a bonding layer underlying at least a portion of the heat sink 409. Such a bonding layer may be present as a layer overlying the HTS layer as previously illustrated, or alternatively, may substantially surround the component layers of the superconducting tape segment 400 like the heat sink 409.

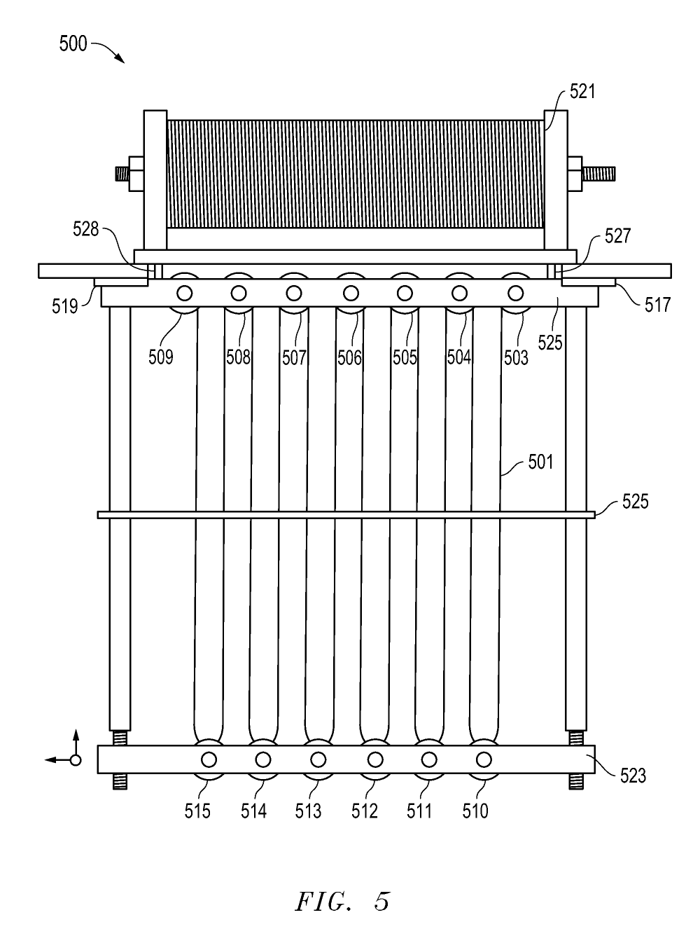

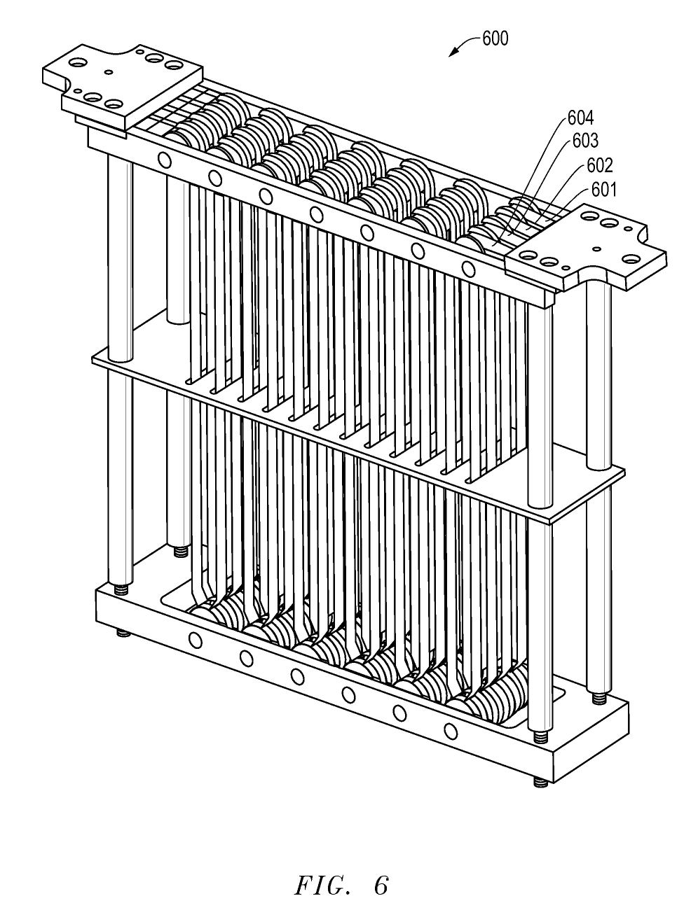

Referring to FIG. 5 a fault current limiter (FCL) article 500 having is illustrated. The FCL article 500 includes at least one superconducting tape segment 501 having a plurality of windings having straight portions and turns, wherein the turns are made around a plurality of contacts 503-515. According to the illustrated embodiment, the superconducting tape segment 501 is suspended between the contacts 503-515 facilitating effective exposure of the superconducting tape segment 501 to a coolant, such as a cryogenic liquid or gas.

Notably, the superconducting tape segment 501 includes a continuous layer of HTS material that is continuous along the length of the windings, typically without utilization of joints or bridges. However, the FCL article may include multiple superconducting tape segments that may be joined by a joint, bridge, or coupling. As such, these joints can be mechanical and electrical coupling devices, which may be particularly useful for joining a plurality of superconducting tape segments in series. Alternatively, a plurality of superconducting tape segments may be joined in a parallel configuration, such as for example, electrically coupled to form a parallel circuit.

The meandering path has a plurality of windings, each of which includes straight portions and turns of the superconducting tape segment 201. As used herein, one winding generally includes any path through which the superconducting tape segment 201 begins and returns to a similar orientation with respect to the contacts. Generally, the superconducting tape segment 501 has a length of not less than about 0.1 m, such as not less than about 5 m, or not less than about 10 m, or even not less than about 1000 m. Typically, the superconducting tape segment 501 has a length that is not greater than about 2 km. Additionally, the superconducting tape segment 501 can have a width of not less than about 1 mm, such as not less than about 10 mm, or even not less than about 100 mm. Generally, the superconducting tape segment 501 can have an average thickness of not less than about 20 microns, such as not less than about 200 microns, or even not less than about 1500 microns. Still, in one embodiment, the average thickness of the superconducting tape segment 501, is not less than about 75 microns, such as not less than about 150 microns. Typically, the average thickness of the superconducting tape segment 501 is within a range of between about 20 microns and about 5 mm, such as between about 50 microns and about 1 mm.

As illustrated in FIG. 5, the superconducting tape segment 501 extends in a meandering path design around a plurality of contacts. According to one embodiment, the superconducting tape segment 501 is suspended. Generally, the superconducting tape segment 501 can be suspended between the contacts to facilitate exposure to a cooling medium. In particular, in one embodiment, not less than about 50% of the total external surface area of the superconducting tape segment 501, and particularly the external surface of the heat sink of the superconducting tape segment 501, is exposed to the cooling medium. In another embodiment, not less than about 75%, such as not less than about 90%, or even not less than about 98% of the total external surface area of the superconducting tape segment 501 is exposed to the cooling medium.

According to one embodiment, the meandering path design of the superconducting tape segment 501 is a non-inductive design, which facilitates reduction of additional impedances during operation of the FCL article. According to the embodiment illustrated in FIG. 5, the superconducting tape segment 501 does not overlap itself along the meandering path. Additionally, the superconducting tape segment travels non-linearly but the tape's ends are displaced a distance “d” from the first contact 503 to a final contact 509.

Generally, the meandering path design of the FCL article includes winding of the superconducting tape segment 501 around a plurality of contacts 503-515. According to some embodiments, a portion of the contacts 503-515 can be electrical contacts, such that not fewer than 2 of the contacts can be electrical contacts. According to another embodiment, the FCL article includes not fewer than 6 electrical contacts, and in some embodiments, not fewer than 10 electrical contacts. As illustrated, the meandering path design can incorporate many more contacts such that the windings of the superconducting tape segment 501 wrap around not fewer than 15 or even 20 contacts. It will be appreciated that the number of contacts may also depend upon the meandering path design and the length of the superconducting tape segment 501. Still, according to the embodiment of FIG. 5, contacts 503-515 are mechanical contacts, while the electrical contacts 527 and 528 are separate from the contacts 503-515 for effective electrical coupling between the superconducting tape segment 501 and the shunting circuit 521.

Generally, the electrical contacts are made of an electrically conductive material or have an electrically conductive coating. Suitable materials for the electrical contacts include a noble metal, such as silver, gold, or non-noble metals such as copper, aluminum or alloys thereof.

In further reference to the design of the FCL article, the contacts can be movable. In one embodiment, a portion of the contacts are spring-loaded or biased within the base facilitating movement of the superconducting tape segment 501 and reducing stress to the tape segment, particularly stress to the tape due to expansion and contraction with changes in temperature. Additionally, a portion of the contacts or all of the contacts can include channels for engaging and positioning the superconducting tape segment 501. The channels facilitate turning the winding of the superconducting tape segment 501 around the contacts, directing the winding to the next contact, and maintaining a non-inductive meandering path design.

The FCL article 500 also includes a shunting circuit 521 electrically coupled to the superconducting tape segment 501 via electrical contacts 527 and 528. The shunting circuit 521 facilitates current flow when the superconducting tape segment 501 is in a non-superconducting state. As illustrated, the FCL article 500 includes one shunting circuit 521 that spans the length of the meandering path of the superconducting tape segment 501.

According to one embodiment, the shunting circuit 521 includes at least one impedance element (i.e., resistors and/or inductors), and more typically, a plurality of impedance elements. In one embodiment, the plurality of impedance elements can be connected in series to each other. The number of impedance elements connected in series is generally greater than about 2, such as not less than about 5, or even not less than about 10 impedance elements. Alternatively, the series of impedance elements can be connected in series with electrical contacts. In one particular embodiment, the series of impedance elements is coupled to each of the electrical contacts.

Generally, the impedance elements are selected to have a particular impedance based upon the length of tape that the shunting circuit spans such that each impedance element protects a certain length of the superconducting tape segment 501. As such, typically the shunting circuit includes impedance elements having an impedance of not less than about 0.01 milliOhms/meter of tape protected. Other embodiments utilize a greater impedance per meter of tape protected, such that the impedance elements have a value of not less than about 1 milliOhms/meter of tape protected, or not less than about 5 milliOhms/meter of tape protected, or even not less than about 10 milliOhms/meter of tape protected, and even up to about 1.0 Ohm/meter of tape protected.

As will be appreciated, the number of impedance elements within the shunting circuit is dependent in part upon the desired impedance per meter of tape protected. Generally, the shunting circuits herein incorporate more than one impedance element per meter of superconducting tape segment. For example, the shunting circuit can incorporate one impedance element for not less than about 5 meters of superconducting tape segment. Other embodiments may use less elements, such as one impedance element for not less than about 10 meters of superconducting tape segment protected, or even one impedance element for not less than about 20 meters of superconducting tape segment protected.

Other embodiments may utilize more than one shunting circuit, each having at least one impedance element. In such embodiments, the multiple shunting circuits can be electrically coupled to the superconducting tape segment through electrical contacts, or alternatively, inductively coupled. Multiple first shunting circuits can span portions of the meandering path as opposed to the full length. More shunting circuits can be included, and according to one embodiment, the FCL device incorporates a shunting circuit contacting each of the electrical contacts to maximize alternative current flow paths in case of damage or failure to the tape.

Moreover, a plate 525 is located between the structures 523 and 525 and contains openings for passage of the superconducting tape segment 501 therethrough. The illustrated embodiment further includes a shunting circuit electrically coupled to the superconducting tape segment 501 through electrical contacts 527 and 528. As such, according to this particular embodiment, the superconducting tape segment 501 does not wrap around the electrical contacts 527 and 528. It will be appreciated that such an embodiment may incorporate multiple superconducting tape segments.

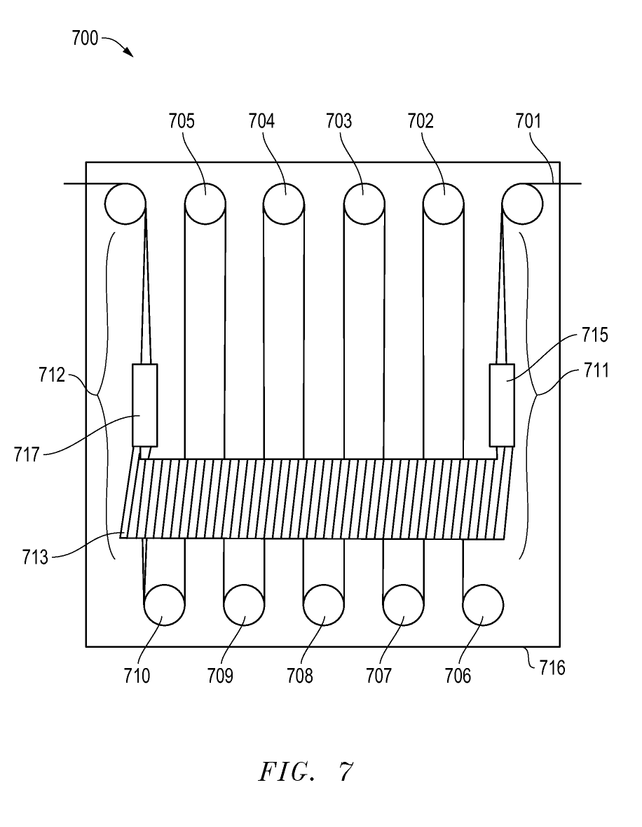

FIG. 6 is a perspective view of a FCL article 600 having a similar configuration to the FCL article 500, however, the FCL article 600 includes multiple superconducting tape segments 601, 602, 603 and 604, each having a plurality of windings comprising straight portions and turns which extend around the plurality of contacts. According to the illustrated embodiment, the superconducting tape segments 601-604 are positioned adjacent to each other, such that the straight portions of each of the superconducting tape segments 601-604 extend along the same plane. Moreover, according to the illustrated embodiment, each of the superconducting tape segments 601-604 have turns which extend around contacts and which are adjacent to each other. More clearly, each of the superconducting tape segments 601-604 have substantially similar paths except that they are displaced a lateral distance from an adjacent tape thereby reducing tape-to-tape electromagnetic interferences. Generally, the average lateral distance between adjacent tapes, as measured from center-of-tape to center-of-tape, is not greater than about 20 cm. Other embodiments may utilize a closer spacing such that the average lateral distance between adjacent tapes is not greater than about 5 cm, such as not greater than about 1 cm, or even not greater than about 0.1 cm.

Referring to FIG. 7, a FCL article 4700 is illustrated that includes a superconducting tape segment 701 having a plurality of windings in an alternative meandering path design. As illustrated, the FCL article 700 includes a plurality of contacts such as 702-710, overlying a base 716. While as described above such contacts 702-710 can include mechanical or electrical contacts, in this particular embodiment, the contacts 702-710 are mechanical contacts for turning the superconducting tape segment 701. Unlike previous described embodiments, the superconducting tape segment 701 includes rotation regions 711 and 712 where the superconducting tape segment 701 is tilted or rotated. According to the illustrated embodiment, the rotation regions 711 and 712 are particularly localized along straight portions of the superconducting tape segment 701. Such rotation regions 711 and 712 facilitate coupling of the superconducting tape segment 701 to electrical contacts 715 and 717, which in turn couple the superconducting tape segment 701 to a shunt circuit 713. Notably, within the rotation regions 711 and 712 the superconducting tape segment 701 is rotated such that at least a portion of the superconducting tape segment 701 is parallel to the base 716 and lies flat against a contact surface of the electrical contacts 715 and 717.

It will be appreciated that according to one embodiment, multiple parallel windings of superconducting tape segments can be incorporated into such an embodiment, all of which may be rotated to facilitate a connection to electrical contacts. According to a particular embodiment, the superconducting tape segment 701 is suspended over the base 719 on its side, such that planes tangential to the top and bottom surfaces of the tape segment are perpendicular or substantially perpendicular to the major plane of the base 719. According to one embodiment, not less than about 75% of the total length of the superconducting tape segment 701 is suspended above the base 719. In another embodiment, not less than about 90% of the total length of the tape segment is suspended, still, in other embodiments, essentially the entire length of the superconducting tape segment 701 is suspended above the base 719.

The FCL articles described herein are particularly suited to maintain high electrical fields during a fault state, particularly electrical fields in excess of 0.1 V/cm. Notably, in one embodiment, the FCL article maintains an electrical field of not less than about 0.5 V/cm, such as not less than about 2.0 V/cm, or even not less than about 5.0 V/cm during a fault state.

Moreover, the FCL articles of the present embodiments have an impedance ratio that is a measure of the impedance between the superconducting tape segment and the shunting circuit when the article is in the non-superconducting state. Generally, the impedance ratio is not less than about 1:1, and more typically, not less than about 5:1 between the superconducting tape segment and the shunting circuit when the article is in the non-superconducting state. According to one embodiment, the impedance ratio is not less than about 20:1, or not less than about 50:1, or even not less than about 100:1. According to a particular embodiment, the impedance ratio of the FCL device is engineered to be within a range of between 5:1 and 30:1.

While the incorporation of heat sinks is known, particularly stainless steel heat sinks (See for example, U.S. Pat. No. 6,762,673), such known articles are limited. For example, such metal heat sinks are generally conductive, having a resistivity of about 10E-8 Ω-m or less. Accordingly, the known heat sinks are particularly unsuitable for incorporation with the presently disclosed FCL articles, as they interfere or alter critical properties of the FCL articles, particularly the magnetic and electrical properties.

In contrast, the FCL articles of the present embodiments represent a departure from the state of the art. The present embodiments provide a combination of features including multi-layered, superconducting tape segments having a specific substrate layer thickness coupled with particular bonding layers and heat sinks of specifically designed thermal conductivity, CTE, electrical resistivity, and thickness for particular applications incorporating suspended, non-inductive, meandering path designs. The combination of such features, among the others described above, has led the inventors to create enhanced performance FCL articles, notably FCL articles capable of maintaining high electrical fields (i.e., greater than 0.5 V/cm) in the fault state and having suitable impedance ratios. In combination with the other features of the FCL articles, the bonding layer and heat sink are purposely designed with select electrical resistivity ranges and select thermal conductivity ranges such that it is capable of shunting a purposefully engineered fraction of electrical current during a fault state while also providing exceptional recovery under load such that the FCL article has rapid response capabilities and dissipates thermal energy quickly. That is, while other commonly known heat sinks have typically used metal and/or conductive materials, the present inventors have discovered that in the context of the FCL articles of the present embodiments, a superconducting tape segment having a bonding layer and heat sink of a particular electrical resistivity, CTE, thermal conductivity, and thickness, results in FCL articles having improved response, performance, and durability not previously recognized.

While the invention has been illustrated and described in the context of specific embodiments, it is not intended to be limited to the details shown, since various modifications and substitutions can be made without departing in any way from the scope of the present invention. For example, additional or equivalent substitutes can be provided and additional or equivalent production steps can be employed. As such, further modifications and equivalents of the invention herein disclosed may occur to persons skilled in the art using no more than routine experimentation, and all such modifications and equivalents are believed to be within the scope of the invention as defined by the following claims.

1. A fault current limiting (FCL) article comprising:
a superconducting tape segment comprising:
a substrate;
a buffer layer overlying the substrate;
a high temperature superconducting (HTS) layer overlying the buffer layer; and
a heat sink overlying the HTS layer, the heat sink comprising a non-metal material, a thermal conductivity of not less than about 0.1 W/m-K at 20° C., and an electrical resistivity of not less than about 1E-5 Ω-m at 20° C.; and
a shunting circuit electrically connected to the superconducting tape segment.

2-5. (canceled)

6. The FCL article of claim 1, wherein the heat sink comprises carbon.

7. The FCL article of claim 6, wherein the heat sink is essentially carbon.

8. The FCL article of claim 1, wherein the heat sink comprises a material selected from the group of material consisting of carbon, silicon, silicon carbide, aluminum nitride, beryllium oxide, and boron nitride.

9. The FCL article of claim 1, wherein the heat sink has an electrical resistivity of not less than about 1E-3 Ω-m at 20° C.

10. (canceled)

11. The FCL article of claim 1, wherein the heat sink comprises a thermal conductivity of not less than about 20 W/m-K at 20° C.

12. (canceled)

13. The FCL article of claim 1, wherein the heat sink comprises a coefficient of thermal expansion (CTE) of not greater than about 300 E-6 K⁻¹ at 20° C.

14. (canceled)

15. The FCL article of claim 1, wherein the heat sink is directly contacting the HTS layer.

16. The FCL article of claim 1, wherein a bonding layer is underlying and directly contacting at least a portion of the heat sink.

17-18. (canceled)

19. The FCL article of claim 1, wherein the heat sink is a conformal layer of material overlying the majority of the length of the HTS layer.

20. The FCL article of claim 19, wherein the heat sink is substantially surrounding the substrate, buffer layer, and HTS layer.

21. (canceled)

22. The FCL article of claim 1, wherein a capping layer is disposed between the HTS layer and the heat sink.

23-24. (canceled)

25. The FCL article of claim 1, wherein the superconducting tape segment is configured to maintain an electric field of greater than about 0.1 V/cm during fault conditions.

26. (canceled)

27. The FCL article of claim 1, wherein the superconducting tape segment forms a meandering path that is continuous, the meandering path having a plurality of windings.

28. The FCL article of claim 1, wherein a portion of the superconducting tape segment is suspended between contacts and exposed to a cooling medium.

29. The FCL article of claim 1, wherein the shunting circuit comprises at least one impedance element.

30. The FCL article of claim 29, wherein the shunting circuit comprises a plurality of impedance elements connected in series.

31. The FCL article of claim 29, wherein the at least one impedance element has an impedance of not less than about 0.01 milliOhms per meter of meander path protected.

32. The FCL article of claim 29, wherein the article has an impedance ratio in the non-superconducting state of not less than about 1:1 between the impedance of the superconducting tape segment and the impedance of the shunting circuit.

33-37. (canceled)

38. A fault current limiting (FCL) article comprising:
a superconducting tape segment comprising:
a substrate having a thickness of less than about 200 microns;
a buffer layer overlying the substrate;
a high temperature superconducting (HTS) layer overlying the buffer layer;
a bonding layer overlying the HTS layer, the bonding layer having a thermal conductivity of not less than about 0.1 W/m-K at 20° C., and an electrical resistivity of not less than about 1E-6 Ω-cm as measured at 20° C.
a heat sink overlying the bonding layer, the heat sink comprising a non-metal material, a thermal conductivity of not less than about 0.1 W/m-K at 20° C., and an electrical resistivity of not less than about 1E-5 Ω-m at 20° C.; and
a shunting circuit electrically connected to the superconducting tape segment.

39-40. (canceled)
